(19) United States
(12) Patent Application Publication
(10) Pub. No.: US 2026/0243831 A1
(43) Pub. Date: Aug. 20, 2026

(54) DIAGNOSTIC TOOL FOR TESTING A THREE-PHASE ELECTRIC MOTOR OF A VEHICLE HYDRAULIC SYSTEM

(71) Applicant: GM Global Technology Operations LLC, Detroit, MI (US)

(72) Inventor: Timothy Michael Gavula, Chesterfield, MI (US)

(21) Appl. No.: 19/058,471

(22) Filed: Feb. 20, 2025

(51) Int. Cl. G01R 31/34; G01D 1/16; G01D 1/18

(52) U.S. Cl. CPC G01R 31/343; G01D 1/16; G01D 1/18

(57) ABSTRACT

A diagnostic tool for a three-phase electric motor that is part of a hydraulic system in a vehicle includes one or more controllers in electronic communication with the three-phase electric motor. The one or more controllers of the diagnostic tool execute instructions to instruct the three-phase electric motor to operate at a minimum operating speed for a minimum speed time interval and a maximum operating speed for a maximum speed time interval. The diagnostic tool determines the three-phase electric motor has not passed a diagnostic test procedure based on actual operating speeds and the current draw of the three-phase electric motor that are monitored by the diagnostic tool during the minimum speed time interval and the maximum speed time interval.

### INTRODUCTION

The present disclosure relates to a diagnostic tool for testing a three-phase electric motor that is part of a vehicle hydraulic system as well as a method for testing the three-phase electric motor by the diagnostic tool.

A vehicle’s fuel pump is responsible for drawing fuel stored in a fuel tank and delivering the fuel to the vehicle’s engine under pressure. Electric fuel pumps have become the standard in vehicles equipped with electronic fuel injection systems. Electric fuel pumps include an electric motor for driving a pumping mechanism. The pumping mechanism is responsible for creating the pressure required to draw fuel into the electric fuel pump as well as push fuel out of the electric fuel pump and into the vehicle’s fuel lines.

It is to be appreciated that an increasing number of electric fuel pumps include a three-phase electric motor. The current approach for diagnosing a three-phase electric motor requires a technician to employ a vehicle’s on-board controls as well as its electrical system to operate the three-phase electric motor. Specifically, the current approach for diagnosing a three-phase electric motor requires the vehicle’s electrical system to be placed in run mode to activate the entire electrical system, however, the vehicle’s engine does not necessarily need to be started. In some instances, the vehicle’s on-board controls and electrical system may present incorrect information, such as false failures, regarding the state of the three-phase electric motor.

Thus, while current diagnostic approaches directed to vehicle fuel pumps achieve their intended purpose, there is a need in the art for an improved approach to diagnose a three-phase electric motor for a fuel pump that does not involve the vehicle’s on-board controls and entire electrical system.

### SUMMARY

According to several aspects, a diagnostic tool for a three-phase electric motor that is part of a hydraulic system in a vehicle is disclosed. The diagnostic tool includes one or more controllers in electronic communication with the three-phase electric motor. The one or more controllers include one or more processors that execute instructions to instruct the three-phase electric motor to operate at a minimum operating speed for a minimum speed time interval while monitoring a rotational speed and a current draw of the three-phase electric motor, where the three-phase electric motor receives electrical power required for operating at the minimum operating speed from a source of direct current (DC) power. The one or more controllers instruct the three-phase electric motor to operate at a maximum operating speed for a maximum speed time interval while monitoring the rotational speed and the current draw of the three-phase electric motor. The one or more controllers compare the rotational speed and the current draw of the three-phase electric motor monitored during the minimum speed time interval with an actual minimum operating speed and a minimum current draw threshold value, and compare the rotational speed and the current draw of the three-phase electric motor monitored during the maximum speed time interval with an actual maximum operating speed and a maximum current draw threshold value. In response to determining one or more of the following: the actual minimum operating speed of the three-phase electric motor deviates more than a threshold speed difference value from the minimum operating speed, the current draw of the three-phase electric motor monitored during the minimum speed time interval exceeds the minimum current draw threshold value, the actual maximum operating speed of the three-phase electric motor deviates more than the threshold speed difference value from the maximum operating speed, and the current draw of the three-phase electric motor monitored during the maximum speed time interval exceeds the maximum current draw threshold value, the one or more controllers determine the three-phase electric motor has not passed a diagnostic test procedure.

In another aspect, the diagnostic tool comprises a display that shows graphics and images.

In yet another aspect, the one or more controllers execute instructions to instruct the display to generate a message indicating the three-phase electric motor has not passed the diagnostic test procedure.

In an aspect, the minimum speed time interval includes a stabilization time interval that allows for the three-phase electric motor to stabilize the rotational speed.

In another aspect, the minimum speed time interval is about eleven seconds.

In yet another aspect, the minimum operating speed is about 3000 revolutions per minute (RPM).

In an aspect, the maximum speed time interval includes a stabilization time interval that allows for the three-phase electric motor to stabilize the rotational speed.

In another aspect, the maximum speed time interval is about eleven seconds.

In yet another aspect, the maximum operating speed is about 6000 RPM.

In an aspect, the one or more controllers execute instructions to instruct the three-phase electric motor to operate at a middle operating speed for a middle speed time interval while monitoring the rotational speed and the current draw of the three-phase electric motor.

In another aspect, the one or more controllers execute instructions to compare the rotational speed and the current draw of the three-phase electric motor monitored during the middle speed time interval with an actual middle operating speed and a middle current draw threshold value, and in response to determining one or more of the following: the actual middle operating speed of the three-phase electric motor deviates more than the threshold speed difference value from the middle operating speed and the current draw of the three-phase electric motor exceeds the middle current draw threshold value, determining the three-phase electric motor has not passed the diagnostic test procedure.

In yet another aspect, the middle speed time interval includes a stabilization time interval that allows for the three-phase electric motor to stabilize the rotational speed.

In an aspect, the middle speed time interval is about eleven seconds.

In another aspect, the middle operating speed is about 4500 RPM.

In still another aspect, the three-phase electric motor receives all electrical power required for operation from the source of DC power as the diagnostic test procedure is executed.

In an aspect, a method for performing a diagnostic test procedure to test a three-phase electric motor by a diagnostic tool. The method includes instructing, by one or more controllers that are part of the diagnostic tool, the three-phase electric motor to operate at a minimum operating speed for a minimum speed time interval while monitoring a rotational speed and a current draw of the three-phase electric motor, where the three-phase electric motor receives electrical power required for operating at the minimum operating speed from a source of direct current (DC) power. The method includes instructing, by the one or more controllers, the three-phase electric motor to operate at a maximum operating speed for a maximum speed time interval while monitoring the rotational speed and the current draw of the three-phase electric motor. The method includes comparing the rotational speed and the current draw of the three-phase electric motor monitored during the minimum speed time interval with an actual minimum operating speed and a minimum current draw threshold value, and comparing the rotational speed and the current draw of the three-phase electric motor monitored during the maximum speed time interval with an actual maximum operating speed and a maximum current draw threshold value. In response to determining one or more of the following: the actual minimum operating speed of the three-phase electric motor deviates more than a threshold speed difference value from the minimum operating speed, the current draw of the three-phase electric motor monitored during the minimum speed time interval exceeds the minimum current draw threshold value, the actual maximum operating speed of the three-phase electric motor deviates more than the threshold speed difference value from the maximum operating speed, and the current draw of the three-phase electric motor monitored during the maximum speed time interval exceeds the maximum current draw threshold value, the method includes determining the three-phase electric motor has not passed the diagnostic test procedure.

In an aspect, the method further comprises instructing, by the one or more controllers, a display that is part of the diagnostic tool to generate a message indicating the three-phase electric motor has not passed the diagnostic test procedure.

In another aspect, the method further comprises instructing, by the one or more controllers, the three-phase electric motor to operate at a middle operating speed for a middle speed time interval while monitoring the rotational speed and the current draw of the three-phase electric motor.

In yet another aspect, the method further comprises comparing the rotational speed and the current draw of the three-phase electric motor monitored during the middle speed time interval with an actual middle operating speed and a middle current draw threshold value, and in response to determining one or more of the following: the actual middle operating speed of the three-phase electric motor deviates more than the threshold speed difference value from the middle operating speed and the current draw of the three-phase electric motor exceeds the middle current draw threshold value, the method includes determining the three-phase electric motor has not passed the diagnostic test procedure.

In an aspect, a method for performing a diagnostic test procedure to test a three-phase electric motor by a diagnostic tool is disclosed. The method includes instructing, by one or more controllers that are part of the diagnostic tool, the three-phase electric motor to operate at a minimum operating speed for a minimum speed time interval while monitoring a rotational speed and a current draw of the three-phase electric motor, where the three-phase electric motor receives electrical power required for operating at the minimum operating speed from a source of direct current (DC) power. The method includes instructing, by the one or more controllers, the three-phase electric motor to operate at a middle operating speed for a middle speed time interval while monitoring the rotational speed and the current draw of the three-phase electric motor. The method includes instructing, by the one or more controllers, the three-phase electric motor to operate at a maximum operating speed for a maximum speed time interval while monitoring the rotational speed and the current draw of the three-phase electric motor. The method includes comparing the rotational speed and the current draw of the three-phase electric motor monitored during the minimum speed time interval with an actual minimum operating speed and a minimum current draw threshold value, comparing the rotational speed and the current draw of the three-phase electric motor monitored during the middle speed time interval with an actual middle operating speed and a middle current draw threshold value, and comparing the rotational speed and the current draw of the three-phase electric motor monitored during the maximum speed time interval with an actual maximum operating speed and a maximum current draw threshold value. In response to determining one or more of the following: the actual minimum operating speed of the three-phase electric motor deviates more than a threshold speed difference value from the minimum operating speed, the current draw of the three-phase electric motor monitored during the minimum speed time interval exceeds the minimum current draw threshold value, the actual middle operating speed of the three-phase electric motor deviates more than the threshold speed difference value from the middle operating speed, the current draw of the three-phase electric motor exceeds the middle current draw threshold value, the actual maximum operating speed of the three-phase electric motor deviates more than the threshold speed difference value from the maximum operating speed, and the current draw of the three-phase electric motor monitored during the maximum speed time interval exceeds the maximum current draw threshold value, the method includes determining the three-phase electric motor has not passed the diagnostic test procedure.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic diagram of a vehicle including a three-phase electric motor for a fuel pump and the disclosed diagnostic tool for testing the three-phase electric motor, according to an exemplary embodiment; and

FIG. 2 is a process flow diagram illustrating a method for performing a diagnostic test procedure by the diagnostic tool shown in FIG. 1, according to an exemplary embodiment.

### DETAILED DESCRIPTION

The following description is merely exemplary in nature and is not intended to limit the present disclosure, application, or uses.

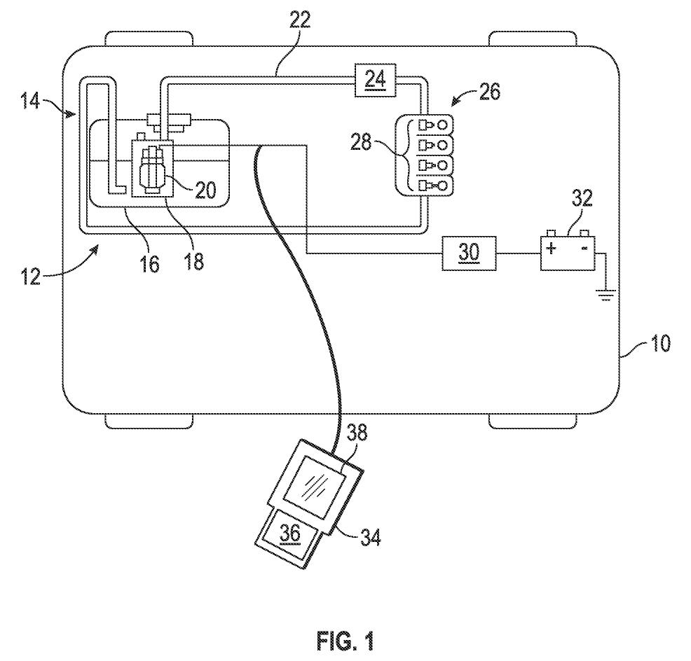

Referring to FIG. 1, a schematic diagram illustrating a vehicle 10 including a hydraulic system 12 is illustrated. It is to be appreciated that the vehicle 10 may be any type of vehicle such as, but not limited to, a sedan, a truck, sport utility vehicle, van, or motor home. In the non-limiting embodiment as shown in the FIG. 1, the hydraulic system 12 is a fuel delivery system 14. The fuel delivery system 14 includes a fuel tank 16 for storing fuel, a fuel pump 18, a three-phase electric motor 20, fuel lines 22, a fuel filter 24, an engine 26, a fuel injection system 28 for the engine 26, and one or more motor controllers 30. In the embodiment as shown, the three-phase electric motor 20 is a fuel pump motor that provides the electric power required by a pumping mechanism (not shown) of the fuel pump 18 to create the pressure required to draw fuel into the fuel pump 18 and push fuel out of the fuel pump 18 and into the fuel lines 22. The engine 26 of the fuel delivery system 14 provides the motive power required to propel the vehicle 10. The fuel lines 22 of the fuel delivery system 14 are for fluidly connecting the fuel tank 16 to the fuel injection system 28 of the engine 26.

Although FIG. 1 illustrates a fuel injection system 28 for delivering fuel to the engine 26, it is to be appreciated that the present disclosure is also directed towards carbureted engines as well. It is also to be appreciated that while FIG. 1 illustrates the hydraulic system 12 as the fuel delivery system 14, FIG. 1 is merely exemplary in nature and the three-phase electric motor 20 may provide the electrical power required by a pumping mechanism that is part of any other hydraulic system in the vehicle 10. Some examples of alternative hydraulic systems 12 where the three-phase electric motor 20 may be employed include, but are not limited to, a power steering system and a coolant system.

The three-phase electric motor 20 of the fuel pump 18 is electrically connected to and receives electrical power from a source of direct current (DC) power 32. In the embodiment as shown in FIG. 1, the source of DC power 32 is a vehicle battery, however, it is to be appreciated that any source of 12 Volt DC power that is either part of the vehicle 10 or is a stand-alone external source that provides the equivalent voltage and amperage of a vehicle battery may be used as well. Some alternative examples of the source of DC power 32 include a vehicle battery charger and a DC power supply that is used in testing procedures. It is to be appreciated that the vehicle battery may also be referred to as a starting, lighting, and ignition (SLI) battery that provides current to a starter motor (not shown) to start the engine 26 of the vehicle 10. The vehicle battery also provides power to various electrical accessories in the vehicle 10 such as, for example, headlights and taillights, a climate control system, and a radio.

FIG. 1 also illustrates a diagnostic tool 34 in electronic communication with the three-phase electric motor 20. It is to be appreciated that the diagnostic tool 34 is directly connected to the three-phase electric motor 20. The diagnostic tool 34 is a stand-alone device that is separate from the vehicle 10. The diagnostic tool 34 includes one or more controllers 36 and a display 38. The one or more controllers 36 of the diagnostic tool 34 instruct the three-phase electric motor 20 to execute a diagnostic testing sequence and monitor the rotational speed and the current draw of the three-phase electric motor 20 as the diagnostic testing sequence is executed. The display 38 generates graphics and images visible to a technician or other individual operating the diagnostic tool 34. In one embodiment, the display 38 may be, for example, a liquid crystal display (LCD).

The diagnostic testing sequence executed by the three-phase electric motor 20 includes operating at a minimum operating speed and at a maximum operating speed. The minimum operating speed refers to the minimum rotational speed at which the three-phase electric motor 20 operates at without loss of speed control and overheating and is based on the cooling capabilities of the three-phase electric motor 20, the phase voltage output used to determine the fuel pump operating speed, and design characteristics such as, for example, the number of turns in an armature, operating voltage, and strength of the motor magnets. Merely by way of example, in one embodiment where the three-phase electric motor 20 is a fuel pump motor, the minimum operating speed is about 3000 revolutions per minute (RPM). The maximum operating speed refers to the speed at which the three-phase electric motor 20 delivers maximum power without overload and overheating and is based on the cooling capabilities of the three-phase electric motor 20, the phase voltage output used to determine the fuel pump operating speed, and the design characteristics. In the embodiment where the three-phase electric motor 20 is a fuel pump motor, the maximum operating speed is about 6000 RPM.

In one non-limiting embodiment, in addition to instructing the three-phase electric motor 20 to operate at the minimum operating speed and at the maximum operating speed, the one or more controllers 36 of the diagnostic tool 34 may also instruct the three-phase electric motor 20 to operate at a middle operating speed. The middle operating speed is an average of the minimum operating speed and at the maximum operating speed. In the present example where the minimum operating speed is about 3000 RPM and the maximum operating speed is 6000 RPM, the middle operating speed is about 4500 RPM.

It is to be appreciated that the three-phase electric motor 20 of the fuel pump 18 receives all of electrical power required for operation from the source of DC power 32 as the diagnostic test procedure is being executed. That is, in other words, the on-board controls and the vehicle electrical system are not required to provide electrical power to the three-phase electric motor 20 as the diagnostic test procedure is being performed.

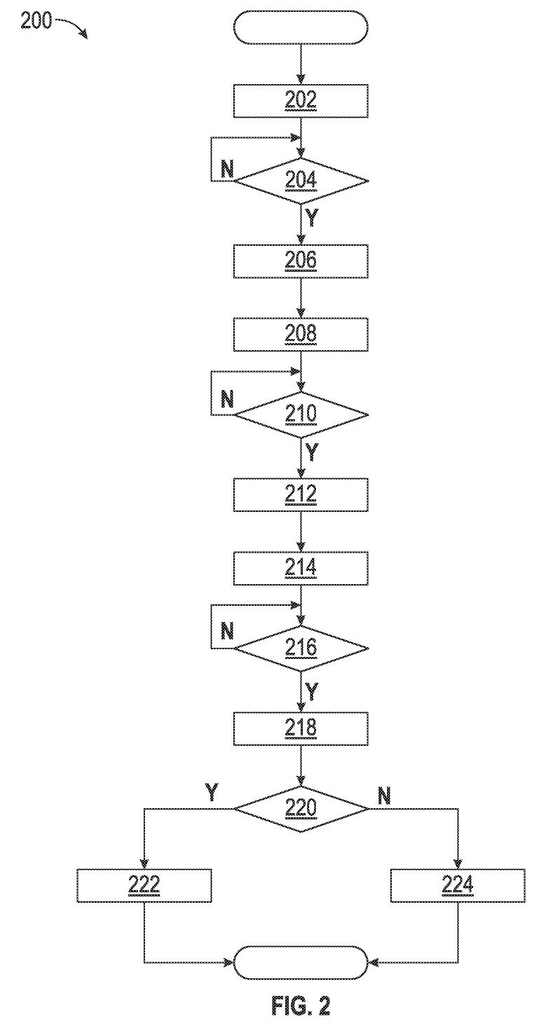

FIG. 2 is a process flow diagram illustrating a method 200 for performing the diagnostic test procedure to test the three-phase electric motor 20 by the diagnostic tool 34. Referring to both FIGS. 1 and 2, the method 200 may begin at block 202. In block 202, the one or more controllers 36 of the diagnostic tool 34 instructs the three-phase electric motor 20 to operate at the minimum operating speed for a minimum speed time interval. It is to be appreciated that the minimum speed time interval may include a stabilization time interval that allows for the three-phase electric motor 20 to stabilize the rotational speed. In one exemplary embodiment, the stabilization time interval is about one second, however, the stabilization time interval may vary based on the application. The minimum speed time interval represents the duration of time required to monitor the rotational speed and the current draw of the three-phase electric motor 20. In one embodiment, the minimum speed time interval is about eleven seconds. The three-phase electric motor 20 receives the electrical power required for operating at the minimum operating speed from the source of DC power 32. The method 200 may then proceed to decision block 204.

In decision block 204, the one or more controllers 36 of the diagnostic tool 34 continue to instruct the three-phase electric motor 20 to operate at the minimum operating speed for the minimum speed time interval while monitoring the rotational speed and the current draw of the three-phase electric motor 20 until the minimum speed time interval has elapsed. In response to determining the minimum speed time interval has elapsed, the method 200 may proceed to block 206.

In block 206, the one or more controllers 36 of the diagnostic tool 34 command the three-phase electric motor 20 to turn off and cease drawing current from the source of DC power 32. The method 200 may then proceed to block 208.

In block 208, the one or more controllers 36 of the diagnostic tool 34 instructs the three-phase electric motor 20 to operate at the middle operating speed for a middle speed time interval. It is to be appreciated that the middle speed time interval may also include the stabilization time interval that allows for the three-phase electric motor 20 to stabilize its rotational speed. The middle speed time interval represents the duration of time required to monitor the rotational speed and the current draw of the three-phase electric motor 20. In one embodiment, the middle speed time interval is about about eleven seconds. It is to be appreciated that the three-phase electric motor 20 receives the electrical power required for operating at the middle operating speed from the source of DC power 32. The method 200 may then proceed to decision block 210.

In decision block 210, the one or more controllers 36 of the diagnostic tool 34 continue to instruct the three-phase electric motor 20 to operate at the middle operating speed for the middle speed time interval while monitoring the rotational speed and the current draw of the three-phase electric motor 20 until the middle speed time interval has elapsed. In response to determining the minimum speed time interval has elapsed, the method 200 may proceed to block 212.

In block 212, the one or more controllers 36 of the diagnostic tool 34 command the three-phase electric motor 20 to turn off and cease drawing current from the source of DC power 32. The method 200 may then proceed to block 214.

In block 214, the the one or more controllers 36 of the diagnostic tool 34 instructs the three-phase electric motor 20 to operate at the maximum operating speed for a maximum speed time interval. It is to be appreciated that the maximum speed time interval may include the stabilization time interval that allows for the three-phase electric motor 20 to stabilize the rotational speed. The maximum speed time interval represents the duration of time required to monitor the rotational speed and the current draw of the three-phase electric motor 20. In one embodiment, the maximum speed time interval is about about eleven seconds. The three-phase electric motor 20 receives the electrical power required for operating at the maximum operating speed from the source of DC power 32. The method 200 may then proceed to decision block 216.

In decision block 216, the one or more controllers 36 of the diagnostic tool 34 continue to instruct the three-phase electric motor 20 to operate at the maximum operating speed for the maximum speed time interval while monitoring the rotational speed and the current draw of the three-phase electric motor 20 until the maximum speed time interval has elapsed. In response to determining the maximum speed time interval has elapsed, the method 200 may proceed to block 218.

In block 218, the one or more controllers 36 of the diagnostic tool 34 command the three-phase electric motor 20 to turn off and cease drawing current from the source of DC power 32. The method 200 may then proceed to decision block 220.

In decision block 220, the one or more controllers 36 compare the rotational speed and the current draw of the three-phase electric motor 20 monitored during the minimum speed time interval with an actual minimum operating speed and a minimum current draw threshold value, the rotational speed and the current draw of the three-phase electric motor monitored during the middle speed time interval with an actual middle operating speed and a middle current draw threshold value, and the rotational speed and the current draw of the three-phase electric motor monitored during the maximum speed time interval with an actual maximum operating speed and a maximum current draw threshold value.

It is to be appreciated that the actual minimum operating speed represents the actual rotational speed of the three-phase electric motor 20 as monitored by the diagnostic tool 34 during the minimum speed time interval and the minimum current draw threshold value represents the maximum expected current draw of the three-phase electric motor 20 when operating at the minimum operating speed. The actual middle operating speed represents the actual rotational speed of the three-phase electric motor 20 as monitored by the diagnostic tool 34 during the middle speed time interval and the middle current draw threshold value represents the maximum expected current draw of the three-phase electric motor 20 when operating at the middle operating speed. The actual maximum operating speed represents the actual rotational speed of the three-phase electric motor 20 as monitored by the diagnostic tool 34 during the maximum speed time interval and the maximum current draw threshold value represents the maximum expected current draw of the three-phase electric motor 20 when operating at the maximum operating speed.

Continuing to refer to decision block 220, in response to determining one or more of the following: the actual minimum operating speed of the three-phase electric motor 20 monitored during the minimum speed time interval deviates more than a threshold speed difference value from the minimum operating speed, the current draw of the three-phase electric motor 20 monitored during the minimum speed time interval exceeds the minimum current draw threshold value, the actual middle operating speed of the three-phase electric motor 20 monitored during the middle speed time interval deviates more than the threshold speed difference value from the middle operating speed, the current draw of the three-phase electric motor 20 monitored during the middle speed time interval deviates exceeds the middle current draw threshold value, the actual maximum operating speed of the three-phase electric motor 20 monitored during the maximum speed time interval deviates more than the threshold speed difference value from the maximum operating speed, and the current draw of the three-phase electric motor 20 monitored during the maximum speed time interval exceeds the maximum current draw threshold value, the one or more controllers 36 of the diagnostic tool 34 determine the three-phase motor 20 has not passed the diagnostic test procedure, and the method 200 may then proceed to block 222. Otherwise, the method proceeds to block 224.

It is to be appreciated that the threshold speed difference value represents a material difference between the actual and commanded speed of the three-phase electric motor 20. In one non-limiting embodiment, the threshold speed difference is about +/- 500 RPM, however, it is to be appreciated that the value of the threshold speed difference may vary based on the specific application.

In block 222, the one or more controllers 36 of the diagnostic tool 34 instruct the display 38 to generate a message indicating the three-phase electric motor 20 has not passed the diagnostic test procedure. For example, in one embodiment, the display 38 of the diagnostic tool 34 may display the message “Fail”. In embodiments, the one or more controllers 36 may also instruct the display 38 to generate a message including the data collected during the diagnostic test procedure as well. The method 200 may then terminate.

In block 224, the one or more controllers 36 of the diagnostic tool 34 instruct the display 38 to generate a message indicating the three-phase electric motor 20 has passed the diagnostic test procedure. For example, in one embodiment, the display 38 of the diagnostic tool 34 may display the message “Pass”. In embodiments, the one or more controllers 36 may also instruct the display 38 to generate a message including the data collected during the diagnostic test procedure as well. The method 200 may then terminate.

Referring generally to the figures, the disclosed diagnostic tool provides various technical effects and benefits. Specifically, the disclosed diagnostic tool provides an approach to determine if the three-phase electric motor that is part of a hydraulic system in a vehicle is operating correctly, without the need to employ a vehicle’s on-board controls as well as its electrical system to operate the three-phase electric motor. Instead, the three-phase electric motor only requires electric power from a source of DC power, such as the vehicle battery.

The controllers may refer to, or be part of an electronic circuit, a combinational logic circuit, a field programmable gate array (FPGA), a processor (shared, dedicated, or group) that executes code, or a combination of some or all of the above, such as in a system-on-chip. Additionally, the controllers may be microprocessor-based such as a computer having at least one processor, memory (RAM and/or ROM), and associated input and output buses. The processor may operate under the control of an operating system that resides in memory. The operating system may manage computer resources so that computer program code embodied as one or more computer software applications, such as an application residing in memory, may have instructions executed by the processor. In an alternative embodiment, the processor may execute the application directly, in which case the operating system may be omitted.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A diagnostic tool for a three-phase electric motor that is part of a hydraulic system in a vehicle, the diagnostic tool comprising:
one or more controllers including one or more processors in electronic communication with the three-phase electric motor, wherein the one or more controllers execute instructions to:
instruct the three-phase electric motor to operate at a minimum operating speed for a minimum speed time interval while monitoring a rotational speed and a current draw of the three-phase electric motor, wherein the three-phase electric motor receives electrical power required for operating at the minimum operating speed from a source of direct current (DC) power;
instruct the three-phase electric motor to operate at a maximum operating speed for a maximum speed time interval while monitoring the rotational speed and the current draw of the three-phase electric motor;
compare the rotational speed and the current draw of the three-phase electric motor monitored during the minimum speed time interval with an actual minimum operating speed and a minimum current draw threshold value, and compare the rotational speed and the current draw of the three-phase electric motor monitored during the maximum speed time interval with an actual maximum operating speed and a maximum current draw threshold value; and
in response to determining one or more of the following: the actual minimum operating speed of the three-phase electric motor deviates more than a threshold speed difference value from the minimum operating speed, the current draw of the three-phase electric motor monitored during the minimum speed time interval exceeds the minimum current draw threshold value, the actual maximum operating speed of the three-phase electric motor deviates more than the threshold speed difference value from the maximum operating speed, and the current draw of the three-phase electric motor monitored during the maximum speed time interval exceeds the maximum current draw threshold value, determine the three-phase electric motor has not passed a diagnostic test procedure.

2. The diagnostic tool of claim 1, further comprising a display that shows graphics and images.

3. The diagnostic tool of claim 2, wherein the one or more controllers execute instructions to:
instruct the display to generate a message indicating the three-phase electric motor has not passed the diagnostic test procedure.

4. The diagnostic tool of claim 1, wherein the minimum speed time interval includes a stabilization time interval that allows for the three-phase electric motor to stabilize the rotational speed.

5. The diagnostic tool of claim 1, wherein the minimum speed time interval is about eleven seconds.

6. The diagnostic tool of claim 1, wherein the minimum operating speed is about 3000 revolutions per minute (RPM).

7. The diagnostic tool of claim 1, wherein the maximum speed time interval includes a stabilization time interval that allows for the three-phase electric motor to stabilize the rotational speed.

8. The diagnostic tool of claim 1, wherein the maximum speed time interval is about eleven seconds.

9. The diagnostic tool of claim 1, wherein the maximum operating speed is about 6000 RPM.

10. The diagnostic tool of claim 1, wherein the one or more controllers execute instructions to:
instruct the three-phase electric motor to operate at a middle operating speed for a middle speed time interval while monitoring the rotational speed and the current draw of the three-phase electric motor.

11. The diagnostic tool of claim 10, wherein the one or more controllers execute instructions to:
compare the rotational speed and the current draw of the three-phase electric motor monitored during the middle speed time interval with an actual middle operating speed and a middle current draw threshold value; and
in response to determining one or more of the following: the actual middle operating speed of the three-phase electric motor deviates more than the threshold speed difference value from the middle operating speed and the current draw of the three-phase electric motor exceeds the middle current draw threshold value, determining the three-phase electric motor has not passed the diagnostic test procedure.

12. The diagnostic tool of claim 10, wherein the middle speed time interval includes a stabilization time interval that allows for the three-phase electric motor to stabilize the rotational speed.

13. The diagnostic tool of claim 10, wherein the middle speed time interval is about eleven seconds.

14. The diagnostic tool of claim 10, wherein the middle operating speed is about 4500 RPM.

15. The diagnostic tool of claim 1, wherein the three-phase electric motor receives all electrical power required for operation from the source of DC power as the diagnostic test procedure is executed.

16. A method for performing a diagnostic test procedure to test a three-phase electric motor by a diagnostic tool, the method comprising:
instructing, by one or more controllers that are part of the diagnostic tool, the three-phase electric motor to operate at a minimum operating speed for a minimum speed time interval while monitoring a rotational speed and a current draw of the three-phase electric motor, wherein the three-phase electric motor receives electrical power required for operating at the minimum operating speed from a source of direct current (DC) power;
instructing, by the one or more controllers, the three-phase electric motor to operate at a maximum operating speed for a maximum speed time interval while monitoring the rotational speed and the current draw of the three-phase electric motor;
comparing the rotational speed and the current draw of the three-phase electric motor monitored during the minimum speed time interval with an actual minimum operating speed and a minimum current draw threshold value, and comparing the rotational speed and the current draw of the three-phase electric motor monitored during the maximum speed time interval with an actual maximum operating speed and a maximum current draw threshold value; and
in response to determining one or more of the following: the actual minimum operating speed of the three-phase electric motor deviates more than a threshold speed difference value from the minimum operating speed, the current draw of the three-phase electric motor monitored during the minimum speed time interval exceeds the minimum current draw threshold value, the actual maximum operating speed of the three-phase electric motor deviates more than the threshold speed difference value from the maximum operating speed, and the current draw of the three-phase electric motor monitored during the maximum speed time interval exceeds the maximum current draw threshold value, determining the three-phase electric motor has not passed the diagnostic test procedure.

17. The method of claim 16, further comprising:
instructing, by the one or more controllers, a display that is part of the diagnostic tool to generate a message indicating the three-phase electric motor has not passed the diagnostic test procedure.

18. The method of claim 16, further comprising:
instructing, by the one or more controllers, the three-phase electric motor to operate at a middle operating speed for a middle speed time interval while monitoring the rotational speed and the current draw of the three-phase electric motor.

19. The method of claim 18, further comprising:
comparing the rotational speed and the current draw of the three-phase electric motor monitored during the middle speed time interval with an actual middle operating speed and a middle current draw threshold value; and
in response to determining one or more of the following: the actual middle operating speed of the three-phase electric motor deviates more than the threshold speed difference value from the middle operating speed and the current draw of the three-phase electric motor exceeds the middle current draw threshold value, determining the three-phase electric motor has not passed the diagnostic test procedure.

20. A method for performing a diagnostic test procedure to test a three-phase electric motor by a diagnostic tool, the method comprising:
instructing, by one or more controllers that are part of the diagnostic tool, the three-phase electric motor to operate at a minimum operating speed for a minimum speed time interval while monitoring a rotational speed and a current draw of the three-phase electric motor, wherein the three-phase electric motor receives electrical power required for operating at the minimum operating speed from a source of direct current (DC) power;
instructing, by the one or more controllers, the three-phase electric motor to operate at a middle operating speed for a middle speed time interval while monitoring the rotational speed and the current draw of the three-phase electric motor;
instructing, by the one or more controllers, the three-phase electric motor to operate at a maximum operating speed for a maximum speed time interval while monitoring the rotational speed and the current draw of the three-phase electric motor;
comparing the rotational speed and the current draw of the three-phase electric motor monitored during the minimum speed time interval with an actual minimum operating speed and a minimum current draw threshold value, comparing the rotational speed and the current draw of the three-phase electric motor monitored during the middle speed time interval with an actual middle operating speed and a middle current draw threshold value, and comparing the rotational speed and the current draw of the three-phase electric motor monitored during the maximum speed time interval with an actual maximum operating speed and a maximum current draw threshold value; and
in response to determining one or more of the following: the actual minimum operating speed of the three-phase electric motor deviates more than a threshold speed difference value from the minimum operating speed, the current draw of the three-phase electric motor monitored during the minimum speed time interval exceeds the minimum current draw threshold value, the actual middle operating speed of the three-phase electric motor deviates more than the threshold speed difference value from the middle operating speed, the current draw of the three-phase electric motor exceeds the middle current draw threshold value, the actual maximum operating speed of the three-phase electric motor deviates more than the threshold speed difference value from the maximum operating speed, and the current draw of the three-phase electric motor monitored during the maximum speed time interval exceeds the maximum current draw threshold value, determining the three-phase electric motor has not passed the diagnostic test procedure.
